(19) United States
(12) Patent Application Publication
(10) Pub. No.: US 2012/0104597 A1
(43) Pub. Date: May 3, 2012

(54) CHIP-ON-CHIP STRUCTURE AND MANUFACTURING METHOD THEROF

(75) Inventors: Tatsuji Ishiduka, Oita-Shi (JP); Junji Yoshikawa, Oita-Shi (JP); Tsutomu Kojima, Oita-Shi (JP)

(73) Assignee: KABUSHIKI KAISHA TOSHIBA, Tokyo (JP)

(21) Appl. No.: 13/069,563

(22) Filed: Mar. 23, 2011

(30) Foreign Application Priority Data
Oct. 29, 2010 (JP) 2010-244475

(51) Int. Cl. H01L 23/485; H01L 21/60

(52) U.S. Cl. 257/737; 438/107; 257/E23.021; 257/E21.508

(57) ABSTRACT

According to an embodiment, a chip-on-chip structure includes a first chip, a second chip, the first chip and the second chip being opposite to each other, a first electrode terminal, a second electrode terminal, a bump and a protecting material. The first electrode terminal is provided on the surface of the first chip at the side of the second chip. The second electrode terminal is provided on the surface of the second chip at the side of the first chip. The bump electrically connects the first electrode terminal and the second electrode terminal. The protecting material is formed around the bump between the first chip and the second chip. The protecting material includes a layer made of a material having heat-sensitive adhesive property.

### CROSS REFERENCE TO RELATED APPLICATION

This application is based upon and claims the benefit of priority from the prior Japanese Patent Application No. 2010-244475 filed on Oct. 29, 2010 in Japan, the entire contents of which are incorporated herein by reference.

### FIELD

Embodiments described herein relate generally to a chip-on-chip structure and a manufacturing method thereof.

### BACKGROUND

A technique of forming a protecting material by pouring an underfill material between chips after bumps are bonded, in order to protect a bump portion of a chip-on-chip structure including upper and lower chips bonded by the bumps, has been known conventionally.

However, the underfill material does not fall within the portion between the chips, but might cover even the side face of the upper chip. Therefore, stress generated in the underfill material increases due to the difference in thermal expansion coefficient (linear expansion coefficient) between the underfill material and the chip. With this, cracks might be produced on the underfill material, so that a wiring on the chip might be broken to deteriorate reliability of the chip-on-chip structure.

### BRIEF DESCRIPTION OF THE DRAWINGS

FIG. 1 is a vertical sectional view of a chip-on-chip structure according to a first embodiment.

FIG. 2 is a partially enlarged view of a region II of the chip-on-chip structure illustrated in FIG. 1.

FIG. 3A is a vertical sectional view illustrating an example of a structure of the chip-on-chip structure, before bumps are bonded, according to the first embodiment.

FIG. 3B is a vertical sectional view illustrating an example of a structure of the chip-on-chip structure, before bumps are bonded, according to the first embodiment.

FIG. 3C is a vertical sectional view illustrating an example of a structure of the chip-on-chip structure, before bumps are bonded, according to the first embodiment.

FIG. 4 is a partially enlarged view of a chip-on-chip structure according to a second embodiment.

FIG. 5A is a vertical sectional view illustrating an example of a structure of the chip-on-chip structure, before bumps are bonded, according to the second embodiment.

FIG. 5B is a vertical sectional view illustrating an example of a structure of the chip-on-chip structure, before bumps are bonded, according to the second embodiment.

FIG. 5C is a vertical sectional view illustrating an example of a structure of the chip-on-chip structure, before bumps are bonded, according to the second embodiment.

### DETAILED DESCRIPTION

According to an embodiment, a chip-on-chip structure includes a first chip, a second chip, the first chip and the second chip being opposite to each other, a first electrode terminal, a second electrode terminal, a bump and a protecting material. The first electrode terminal is provided on the surface of the first chip at the side of the second chip. The second electrode terminal is provided on the surface of the second chip at the side of the first chip. The bump electrically connects the first electrode terminal and the second electrode terminal. The protecting material is formed around the bump between the first chip and the second chip. The protecting material includes a layer made of a material having heat-sensitive adhesive property.

### First Embodiment

### (Configuration of Semiconductor Apparatus)

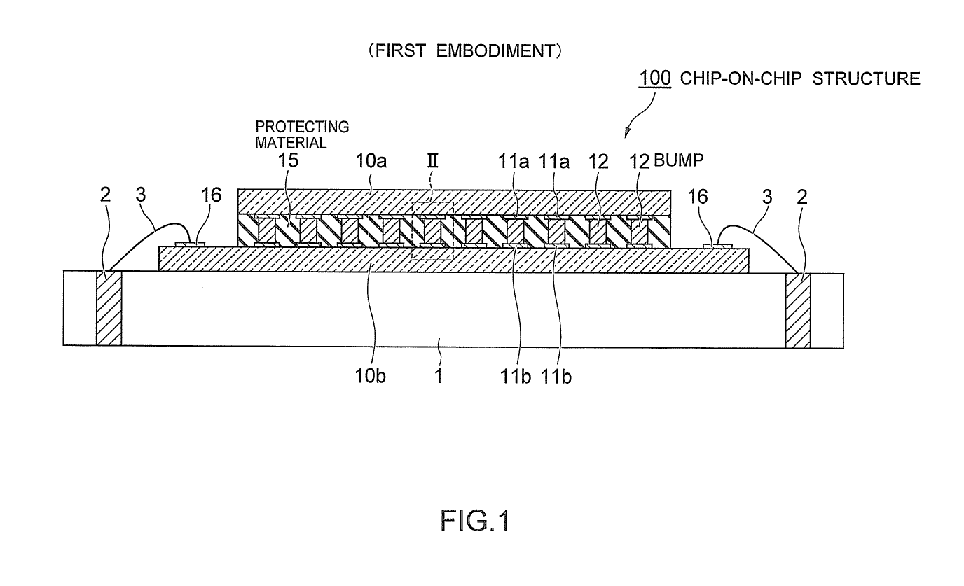

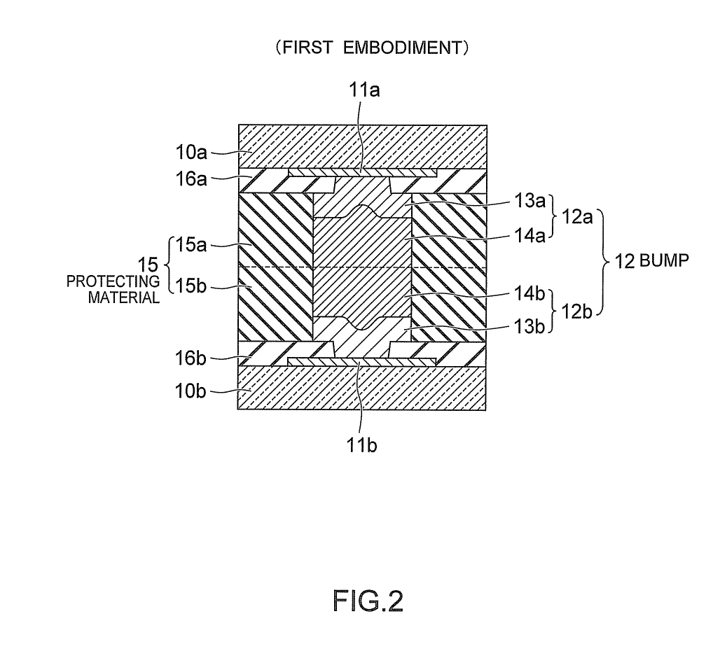

FIG. 1 is a vertical sectional view of a chip-on-chip structure according to a first embodiment. FIG. 2 is a partially enlarged view of a region II of the chip-on-chip structure illustrated in FIG. 1.

A chip-on-chip structure 100 includes an upper chip 10a and a lower chip 10b, which are opposite to each other, electrode terminals 11a on the surface of the upper chip 10a at the side of the lower chip 10b, electrode terminals 11b on the surface of the lower chip 10b at the side of the upper chip 10a, bumps 12 that electrically connect the electrode terminals 11a and the electrode terminals 11b, and a protecting material 15 formed around the bumps 12 between the upper chip 10 and the lower chip 10b.

The upper chip 10a and the lower chip 10b are made of Si or the like. The electrode terminals 11a and 11b are made of a conductive material such as Al.

A passivation film 16a is formed on the upper chip 10a so as to cover the electrode terminals 11a. A passivation film 16b is formed on the lower chip 10b so as to cover the electrode terminals 11b. The passivation films 16a and 16b are made of SiN, TEOS, or a laminate film thereof. An organic film such as a silicon oxide film or a polyimide film may be used as the material for the passivation films 16a and 16b.

The bump 12 is formed by bonding a bump 12a on the electrode terminal 11a and a bump 12b on the electrode terminal 11b. The bump 12a includes a lower bump 13a on the electrode terminal 11a and an upper bump 14a on the lower bump 13a. The bump 12b includes a lower bump 13b on the electrode terminal 11b and an upper bump 14b on the lower bump 13b. In other words, the bump 12a is formed by forming the lower bump 13a on the electrode terminal 11a, and forming the upper bump 14a on the lower bump 13a. The bump 12b is formed by forming a lower bump 13b on the electrode terminal 11b, and forming an upper bump 14b on the lower bump 13b.

The lower bumps 13a and 13b are made of Ni, for example. The upper bumps 14a and 14b are made of Sn, SnCu, or SnAg, for example. The upper bump 14a and the upper bump 14b are brought into contact with each other, and with this state, they are subject to a heat treatment, whereby the upper bump 14a and the upper bump 14b are bonded to each other.

The protecting material 15 has a function of increasing strength at a bonding part of the bump 12 of the chip-on-chip structure 100.

The protecting material 15 is formed by bonding a protecting material 15a around the bump 12a and a protecting material 15b around the bump 12b. The protecting materials 15a and 15b are brought into contact with each other, and in this state, they are subject to a heat treatment in order to be bonded to each other. The bonding of the protecting materials 15a and 15b and the bonding of the bumps 12a and 12b can be performed with the same heat treatment process.

The protecting materials 15a and 15b are made of a material having heat-sensitive adhesive property. For example, an insulating material having a low melting point such as an organic material, or an insulating material whose adhesive property increases through the application of heat, such as silicon oxide, can be used as the material having heat-sensitive adhesive property. The protecting materials 15a and 15b are formed by a coating method and the like, after the formation of the bumps 12a and 12b. The protecting materials 15a and 15b may be formed before the formation of the bumps 12a and 12b.

An electrode pad 16 on the lower chip 10 is connected to a conductive member such as a penetrating contact plug 2 of a substrate 1 through a bonding wire 3.

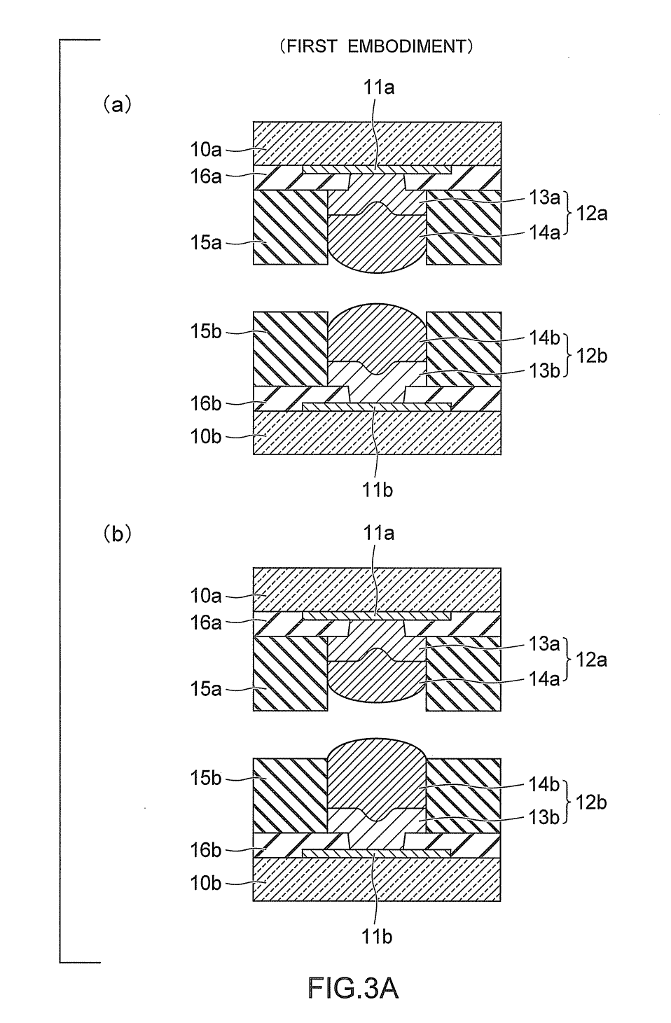

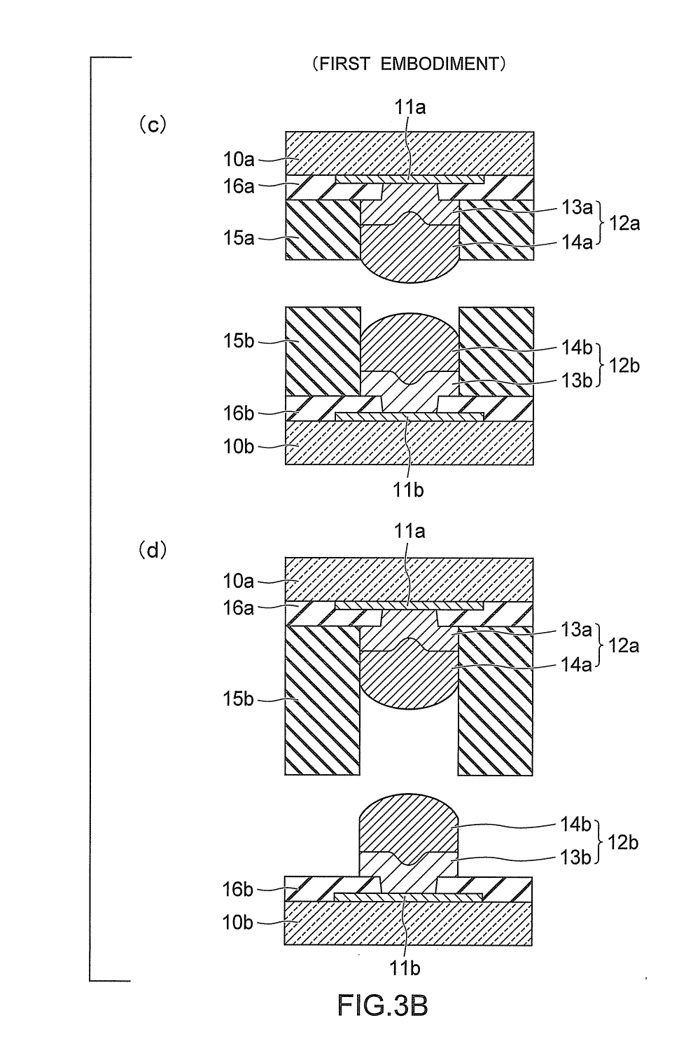

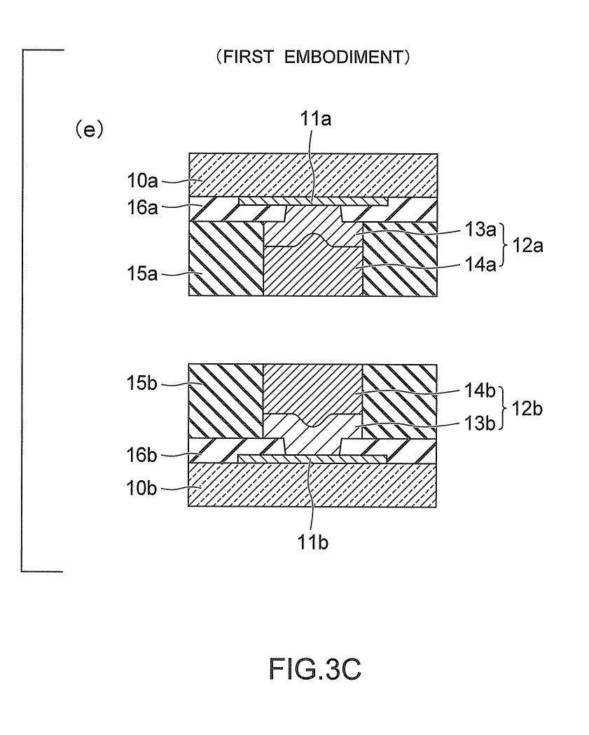

FIGS. 3A(a) and (b), 3B(c) and (d), and 3C(e) are vertical sectional views illustrating an example of the structure before the bump 12a and the bump 12b are bonded.

FIG. 3A(a) illustrates the structure in which the height of the bump 12a and the height of the protecting material 15a are substantially equal to each other, and the height of the bump 12b and the height of the protecting material 15b are substantially equal to each other.

FIG. 3A(b) illustrates the structure in which the height of the bump 12a and the height of the bump 12b are different from each other, and the ratio of the height of the bump 12a to the height of the protecting material 15a is different from the ratio of the height of the bump 12b to the height of the protecting material 15b. In this example, the height of the protecting materials 15a and the height of the protecting material 15b are substantially equal to each other. The bump 12a may be higher than the bump 12b, or vice versa.

FIG. 3B(c) illustrates the structure in which the height of the protecting material 15a and the height of the protecting material 15b are different from each other, and the ratio of the height of the bump 12a to the height of the protecting material 15a is different from the ratio of the height of the bump 12b to the height of the protecting material 15b. In this example, the height of the bump 12a and the height of the bump 12b are substantially equal to each other. The protecting material 15a may be higher than the protecting material 15b, or vice versa.

FIG. 3B(d) illustrates the structure in which either one of the protecting material 15a or the protecting material 15b is formed. In this case, the protecting material 15 is composed of either one of the protecting material 15a or the protecting material 15b. The protecting material 15a may be formed, or vice versa.

The height of the bumps 12a and 12b and the protecting materials 15a and 15b can be adjusted after they are formed. For example, a recess process is performed to both or one of the protecting material 15a and the protecting material 15b, in order to decrease their height. As described next, a planarization process is performed to the bumps 12a and 12b, whereby the height of the bumps 12a and 12b can be correctly aligned with regard to the height of the protecting materials 15a and 15b. Only either one of the bump 12a or the bump 12b may be subject to the planarization process.

FIG. 3C(e) illustrates the structure in which the bumps 12a and 12b are planarized before the bonding. The planarization is made by a polishing process such as CMP (Chemical Mechanical Polishing). With the planarization process, the height of the bumps 12a and 12b can be correctly aligned with regard to the height of the protecting materials 15a and 15b.

In a conventional method in which an underfill material is poured between chips to form the protecting material after the bumps are bonded, the bonding portion spreads in the horizontal direction during the bonding, and as a result, the adjacent bumps might be short-circuited. On the other hand, according to the present embodiment, since the bumps 12a and 12b are enclosed by the protecting materials 15a and 15b during the bonding, the bonding portion does not widely spread in the horizontal direction, whereby the short-circuiting can be prevented. When the bumps 12a and 12b are planarized, the spread at the bonding portion can more effectively be suppressed.

The conventional protecting material made of the underfill material that is poured between the chips after the bumps are bonded does not fall within the region between the upper chip and the lower chip, but might cover even the side face of the upper chip.

However, the protecting material 15 does not greatly protrude from the region between the upper chip 10a and the lower chip 10b. Therefore, stress generated in the protecting material 15 due to the difference in thermal expansion coefficient (linear expansion coefficient) between the protecting material 15 and the upper chip 10a is suppressed. Accordingly, it can be prevented that cracks are generated on the protecting material 15, and the wiring on the lower chip 10b is broken.

### Second Embodiment

The second embodiment is different from the first embodiment in that only a part of the protecting material is made of a heat-sensitive adhesive material. The description of the points which are same as those in the first embodiment will be skipped or simplified.

### (Configuration of Semiconductor Apparatus)

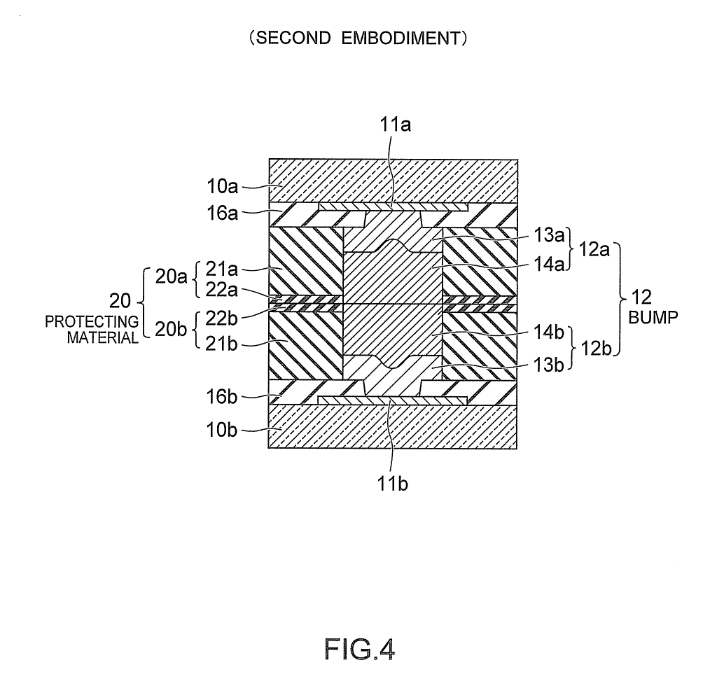

FIG. 4 is a partially enlarged view of a chip-on-chip structure according to the second embodiment. The region illustrated in FIG. 4 corresponds to the region in FIG. 2. The configuration of the chip-on-chip structure other than the protecting material is the same as that in the first embodiment.

The protecting material 20 is formed around the bump 12 between the upper chip 10a and the lower chip 10b like the protecting material 15 in the first embodiment.

The protecting material 20 is formed by bonding a protecting material 20a around the bump 12a and a protecting material 20b around the bump 12b. The bonding of the protecting materials 20a and 20b and the bonding of the bumps 12a and 12b can be made with the same heat treatment process.

The protecting material 20a includes a lower protecting material 21a on a passivation film 16a and an upper protecting material 22a on the lower protecting material 21a. The protecting material 20b includes a lower protecting material 21b on a passivation film 16b and an upper protecting material 22b on the lower protecting material 21b.

The upper protecting materials 22a and 22b are made of a material having heat-sensitive adhesive property. For example, an insulating material having a low melting point such as an organic material, or an insulating material whose adhesive property increases through the application of heat, such as silicon oxide, can be used as the material having heat-sensitive adhesive property. The lower protecting materials 21a and 21b are made of an insulating material such as polyimide or phenolic resin. The material for the lower protecting materials 21a and 21b may not have heat-sensitive adhesive property. The upper protecting material 22a and the upper protecting material 22b are brought into contact with each other, and with this state, they are subject to a heat treatment, whereby the protecting material 20a and the protecting material 20b are bonded to each other.

Only either one of the upper protecting material 22a or the upper protecting material 22b may be formed.

When only the upper protecting material 22a is formed, the upper protecting material 22a and the lower protecting material 21b are bonded. When only the upper protecting material 22b is formed, the upper protecting material 22b and the lower protecting material 21b are bonded.

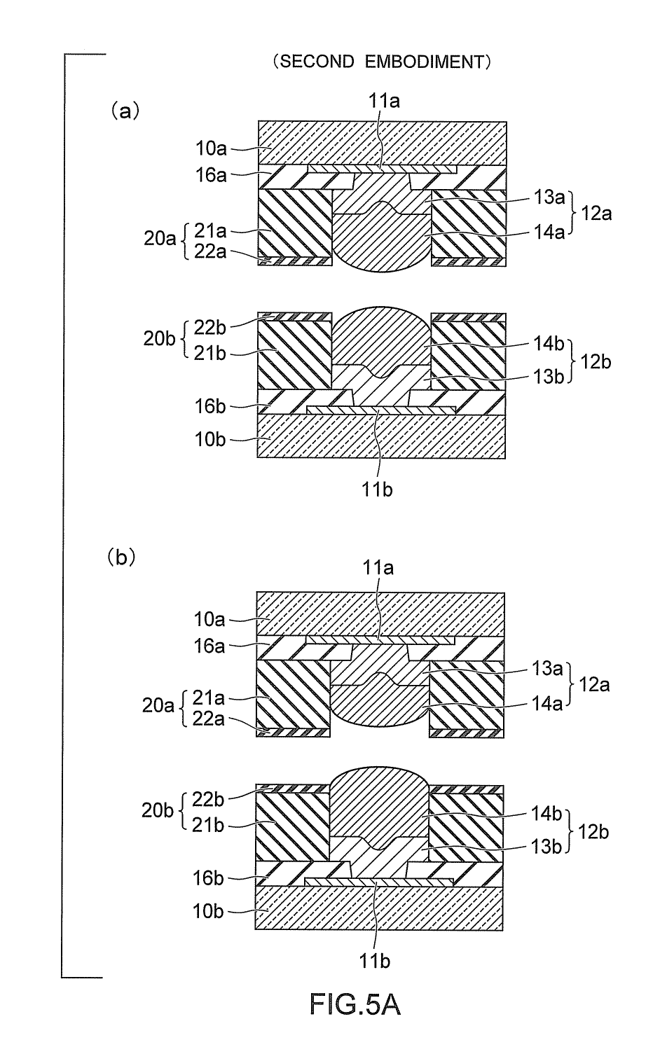

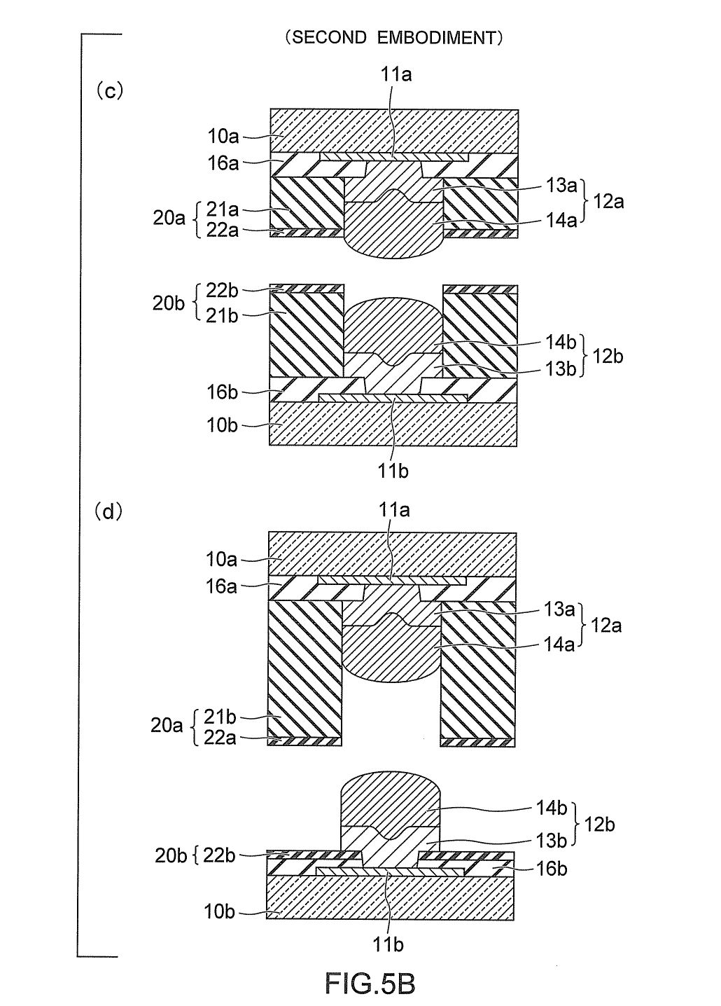

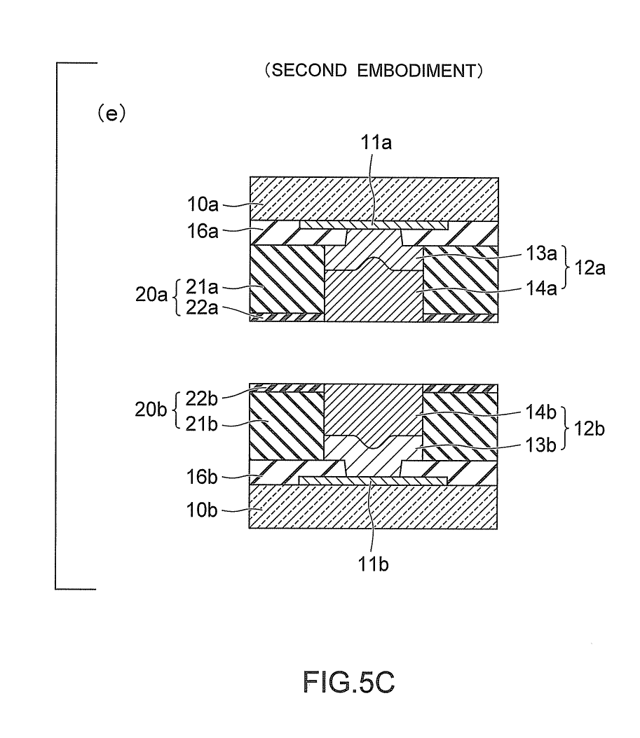

FIGS. 5A(a), (b), FIGS. 5B(c), (d), and FIG. 5C(e) are vertical sectional views illustrating an example of a structure before the bumps 12a and 12b are bonded.

FIG. 5A(a) illustrates the structure in which the height of the bump 12a and the height of the protecting material 20a are substantially equal to each other, and the height of the bump 12b and the height of the protecting material 20b are substantially equal to each other. Only either one of the upper protecting material 22a or the upper protecting material 22b may be formed.

FIG. 5A(b) illustrates the structure in which the height of the bump 12a and the height of the bump 12b are different from each other, wherein the ratio of the height of the bump 12a to the height of the protecting material 20a is different from the ratio of the height of the bump 12b to the height of the protecting material 20b. In this example, the height of the protecting material 15a and the height of the protecting material 15b are substantially equal to each other. The bump 12a may be higher than the bump 12b, or vice versa. Only either one of the upper protecting material 22a or the upper protecting material 22b may be formed.

FIG. 5B(c) illustrates the structure in which the height of the protecting material 20a and the height of the protecting material 20b are different from each other, wherein the ratio of the height of the bump 12a to the height of the protecting material 20a is different from the ratio of the height of the bump 12b to the height of the protecting material 20b. In this example, the height of the bump 12a and the height of the bump 12b are substantially equal to each other. The protecting material 20a may be higher than the protecting material 20b, or vice versa. Only either one of the upper protecting material 22a or the upper protecting material 22b may be formed.

FIG. 5B(d) illustrates the structure in which only either one of the lower protecting material 21a or the lower protecting material 21b is formed. In this case, the protecting material 20 is composed of either one of the lower protecting material 21a and the lower protecting material 21b, or the upper protecting materials 22a and 22b. When only the lower protecting material 21a is formed, the upper protecting material 22b is directly formed on the passivation film 16b. When only the lower protecting material 21b is formed, the upper protecting material 22a is directly formed on the passivation film 16a.

Either one of the lower protecting material 21a or the lower protecting material 21b, and either one of the upper protecting material 22a or the upper protecting material 22b may be formed. In this case, the considerable structures include the one in which the lower protecting material 21a and the upper protecting material 22a is formed, the one in which the lower protecting material 21b and the upper protecting material 22b is formed, the one in which the lower protecting material 21a and the upper protecting material 22b is formed, and the one in which the lower protecting material 21b and the upper protecting material 22a is formed.

FIG. 5C(e) illustrates the structure in which the bumps 12a and 12b are planarized before they are bonded. The bumps 12a and 12b are planarized with a polishing process such as CMP. The height of the bumps 12a and 12b can correctly be aligned with the height of protecting materials 20a and 20b with the planarization process. Only either one of the upper protecting material 22a or the upper protecting material 22b may be formed.

### Effect of the Embodiment

According to the first and second embodiments, the protecting material can be formed so as to substantially fall within the region between the upper chip and the lower chip, whereby the generation of cracks on the protecting material can be prevented. Accordingly, the deterioration in reliability of the chip-on-chip structure due to the brake of the wiring on the chip can be prevented.

Since the bump on the upper chip and the bump on the lower chip are enclosed by the protecting material when they are bonded, the bonding portion does not widely spread, whereby the short-circuiting between the adjacent bumps can be prevented.

### Another Embodiment

The present invention is not limited to the above-mentioned embodiments, but various modifications are possible without departing from the scope of the present invention. Further, the components in the above-mentioned embodiments can optionally be combined without departing from the scope of the present invention.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A chip-on-chip structure comprising:
a first chip;
a second chip, the first chip and the second chip being opposite to each other;
a first electrode terminal on the surface of the first chip at the side of the second chip;
a second electrode terminal on the surface of the second chip at the side of the first chip;
a bump that electrically connects the first electrode terminal and the second electrode terminal; and
a protecting material formed around the bump between the first chip and the second chip, the protecting material comprising a layer made of a material having heat-sensitive adhesive property.

2. The chip-on-chip structure according to claim 1, wherein the protecting material is composed of the layer made of the material having the heat-sensitive adhesive property.

3. The chip-on-chip structure according to claim 1, wherein
the protecting material comprises:
a first lower protecting layer arranged between the layer made of the material having the heat-sensitive adhesive property and the first chip; and
a second lower protecting layer arranged between the layer made of the material having the heat-sensitive adhesive property and the second chip, wherein
the first lower protecting layer and the second lower protecting layer are made of an insulating material.

4. The chip-on-chip structure according to claim 1, wherein
the material having heat-sensitive adhesive property is an insulating material having a low melting point, or an insulating material whose adhesive property increases through the application of heat.

5. The chip-on-chip structure according to claim 4, wherein
the insulating material having the low melting point is an organic material, and
the insulating material whose adhesive property increases through the application of heat is silicon oxide.

6. The chip-on-chip structure according to claim 1, wherein
the bump comprises:
a first lower bump on the first electrode terminal;
a second lower bump on the second electrode terminal; and
an upper bump arranged between the first lower bump and the second lower bump.

7. The chip-on-chip structure according to claim 6, wherein
the first lower bump and the second lower bump are made of Ni, and
the upper bump is made of Sn, SnCu, or SnAg.

8. The chip-on-chip structure according to claim 1, further comprising:
a first passivation film arranged between the first chip and the protecting material; and
a second passivation film arranged between the second chip and the protecting material.

9. A manufacturing method of a chip-on-chip structure comprising:
forming a first bump on a first electrode terminal on a first chip;
forming a second bump on a second electrode terminal on a second chip;
forming a protecting material around at least one of the first bump on the first chip and the second bump on the second chip; and
bonding the first bump and the second bump with a heat treatment, and filling the surrounding of the first bump and the second bump between the first chip and the second chip with the protecting material.

10. The manufacturing method of a chip-on-chip structure according to claim 9, wherein
the protecting material is formed on both of the first chip and the second chip;
the protecting material on the first chip and the protecting material on the second chip are bonded by the heat treatment; and
a portion of at least one of the protecting material on the first chip and the protecting material on the second chip, the portion comprising a bonding surface, is made of a material having heat-sensitive adhesive property.

11. The manufacturing method of a chip-on-chip structure according to claim 9, wherein
the protecting material is formed only on the first chip, and
a portion of the protecting material comprising a bonding surface is made of a material having heat-sensitive adhesive property.

12. The manufacturing method of a chip-on-chip structure according to claim 9, wherein
top portions of the first bump and the second bump are respectively planarized, and the planarized surfaces are bonded to each other.

13. The manufacturing method of a chip-on-chip structure according to claim 10, wherein
top portions of the first bump and the second bump are respectively planarized, and the planarized surfaces are bonded to each other,
the height of the planarized first bump is aligned to the height of the protecting material formed on the first chip; and
the height of the planarized second bump is aligned to the height of the protecting material formed on the second chip.

14. The manufacturing method of a chip-on-chip structure according to claim 10, wherein
the protecting material on the first chip is formed to have the height equal to the height of the first bump, and
the protecting material on the second chip is formed to have the height equal to the height of the second bump.

15. The manufacturing method of a chip-on-chip structure according to claim 10, wherein
the first bump and the second bump are formed so that the height of the first bump is different from the height of the second bump, and
the protecting material is formed so that the ratio of the height of the first bump to the height of the protecting material on the first chip is different from the ratio of the height of the second bump to the height of the protecting material on the second chip.

16. The manufacturing method of a chip-on-chip structure according to claim 10, wherein
the protecting material is formed so that:
the height of the protecting material on the first chip is different from the height of the protecting material on the second chip, and
the ratio of the height of the first bump to the height of the protecting material on the first chip is different from the ratio of the height of the second bump to the height of the protecting material on the second chip.

17. The manufacturing method of a chip-on-chip structure according to claim 9, wherein
the first bump is formed by forming a first lower bump on the first electrode terminal, and by forming a first upper bump on the first lower bump,
the second bump is formed by forming a second lower bump on the second electrode terminal, and by forming a second upper bump on the second lower pump, and
the first bump and the second bump are bonded by bonding the first upper bump and the second upper bump.

18. The manufacturing method of a chip-on-chip structure according to claim 17, wherein
the first lower bump and the second lower bump are made of Ni, and
the first upper bump and the second upper bump are made of Sn, SnCu, or AnAg.

19. The manufacturing method of a chip-on-chip structure according to claim 9, further comprising:
adjusting the height of the first bump, the second bump, and the protecting material, before the first bump and the second bump are bonded, and after the first bump, the second bump, and the protecting material are formed.
